(19) United States
(12) Patent Application Publication
(10) Pub. No.: US 2012/0249175 A1
(43) Pub. Date: Oct. 4, 2012

(54) CONVEYOR-MOUNTABLE CARRIER FOR ELECTRONIC DEVICE TESTING

(75) Inventors: Daniel J. Boatright, Tigard, OR (US); Douglas J. Garcia, Beaverton, OR (US)

(73) Assignee: ELECTRO SCIENTIFIC INDUSTRIES, INC., Portland, OR (US)

(21) Appl. No.: 13/077,177

(22) Filed: Mar. 31, 2011

(51) Int. Cl. G01R 31/00

(52) U.S. Cl. 324/756.01

(57) ABSTRACT

A conveyor mountable carrier is adapted to test an electronic device that has electrical leads. The carrier includes a body having a clamping area defined by a base surface and at least one lateral stop surface. The body also defines a pneumatic channel for directing pressurized air toward the clamping area. A clamp is movably connected to the body and has an engaging portion that is positioned opposite the stop surface of the body. The clamp is moveable between an engaged position in which the electronic device is securable to the body and a disengaged position in which the electronic device is releasable from the body.

### FIELD OF THE INVENTION

The disclosure relates to the field of electronic device testing and, more particularly, to a conveyor-mountable carrier for transporting electronic devices.

### BACKGROUND

Many electronic devices are tested for electrical and optical properties during manufacturing. It is common practice to build a volume of devices with electrical and optical properties which generally fall within a range and rely on testing to sort the devices into commercially useful groups with similar characteristics. Test systems use precision electrical or optical test equipment to find values associated with electrical and optical properties of a device and either accept, reject or sort it into an output category depending upon the measured values.

Automated manufacturing and test systems have been applied in many fields of endeavor. Many of these systems, however, contemplate handling large scales workpieces. Such systems typically could not easily be scaled down and readily adapted for use with small workpieces, such as miniature electronic components.

### SUMMARY

Apparatuses for transporting electronic devices during testing are taught herein, including conveyor-mountable carriers for transporting the electronic devices.

One conveyor mountable carrier taught herein is adapted to test an electronic device that has electrical leads. The carrier includes a body having a clamping area defined by a base surface and at least one lateral stop surface. The body also defines a pneumatic channel for directing pressurized air toward the clamping area. A clamp is movably connected to the body and has an engaging portion that is positioned opposite the stop surface of the body. The clamp is moveable between an engaged position in which the electronic device is securable to the body and a disengaged position in which the electronic device is releasable from the body.

Another conveyor mountable carrier for testing an electronic device having electrical leads includes a body, a clamp and a biasing structure. The body has a clamping area that is defined by a base surface and at least one lateral stop surface. The body also defines a pneumatic channel for directing pressurized air toward the clamping area. The clamp is movably connected to the body and has an engaging portion that is opposite the lateral stop surface of the body. The clamp is moveable between an engaged position in which the engaging portion and the lateral stop surface are engageable with the electronic device for securing the electronic device with respect to the body and a disengaged position in which the electronic device is releasable from the body. The biasing structure is configured to bias the clamp toward the engaged position.

A system for testing electronic devices having electrical leads is also taught herein. The system includes a conveyor that extends between a loading station, a testing station and an unloading station. A carrier is mounted to the conveyor for movement therewith. The carrier includes a body having a clamping area that is defined by a base surface and at least one lateral stop surface, and a pneumatic channel for directing pressurized air toward the clamping area. A clamp is moveably connected to the body and has an engaging portion that is positioned opposite the stop surface of the body. The clamp is moveable between an engaged position, in which the electronic device is securable to the body, and a disengaged position, in which the electronic device is releasable from the body. The carrier has a biasing structure that is configured to bias the clamp toward the engaged position. An actuator is positioned at each of the loading station and the unloading station for moving the clamp from the engaged position to the disengaged position.

### BRIEF DESCRIPTION OF THE DRAWINGS

The description herein makes reference to the accompanying drawings wherein like reference numerals refer to like parts throughout the several views, and wherein:

FIG. 1 is a top down view showing an automated test system;

FIG. 2 is a perspective view of a carrier of the automated test system of FIG. 1;

FIG. 3 is a cross-sectional end view showing the carrier of FIG. 2 and a conveyor of the automated test system of FIG. 1;

FIG. 4 is a top view showing a device retainer of the carrier of FIG. 2;

FIG. 5 is a cross-sectional side view of the device retainer of FIG. 4;

FIG. 6 is a cross-sectional side view of the device retainer of FIG. 4 and a manifold, wherein a clamping structure is in an engaged position;

FIG. 7 is a cross-sectional side view of the device retainer of FIG. 4 and a manifold, wherein a clamping structure is in a disengaged position;

FIG. 8 is a cross-sectional side view of the device retainer of FIG. 4 and an actuating assembly, wherein a clamping structure is in an engaged position; and

FIG. 9 is a cross-sectional side view of the device retainer of FIG. 4 and an actuating assembly, wherein a clamping structure is in a disengaged position.

### DETAILED DESCRIPTION

While automated manufacturing and test systems are known, existing systems are not generally useful with respect to miniature electronic components such as LEDs. Handling LEDs using automated equipment is challenging due to the small size of the LEDS. Other challenges associated with testing and sorting LEDs includes the fact that LEDs need to have their light output tested. Since LEDs can have contacts on one side of the package and light emitting surfaces on the other, the test equipment must probe from one side and collect light output from the other. Another challenge is that light output test equipment is often physically large and needs to be in proximity to the LED under test, which constrains the physical layout of the test equipment. In addition, if parallel testing is to be performed, where multiple test stations are arranged to test multiple devices simultaneously, room for multiple bulky optical test stations needs to be arranged.

The throughput achieved by an electronic device testing system depends upon the time required to test an electronic device as well as the time between successive tests. After a test is completed, a new electronic device is brought into registration with a test system at a testing workstation. If the time required for bringing the new device into registration with the testing system is reduced, throughput is increased. However, the electronic device must be accurately positioned with respect to the test system in order to allow the electronic device to be probed and to allow the response of the device to be monitored. The LEDs must also be secured during transport so that they do not become dislodged. These problems are exacerbated for LEDs due to their many testing requirements.

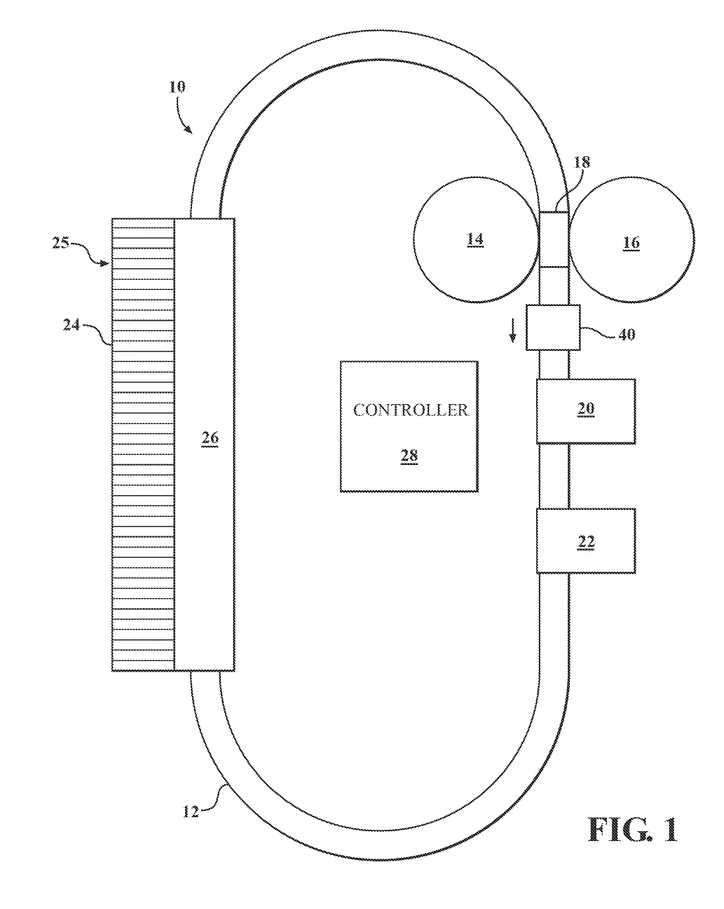

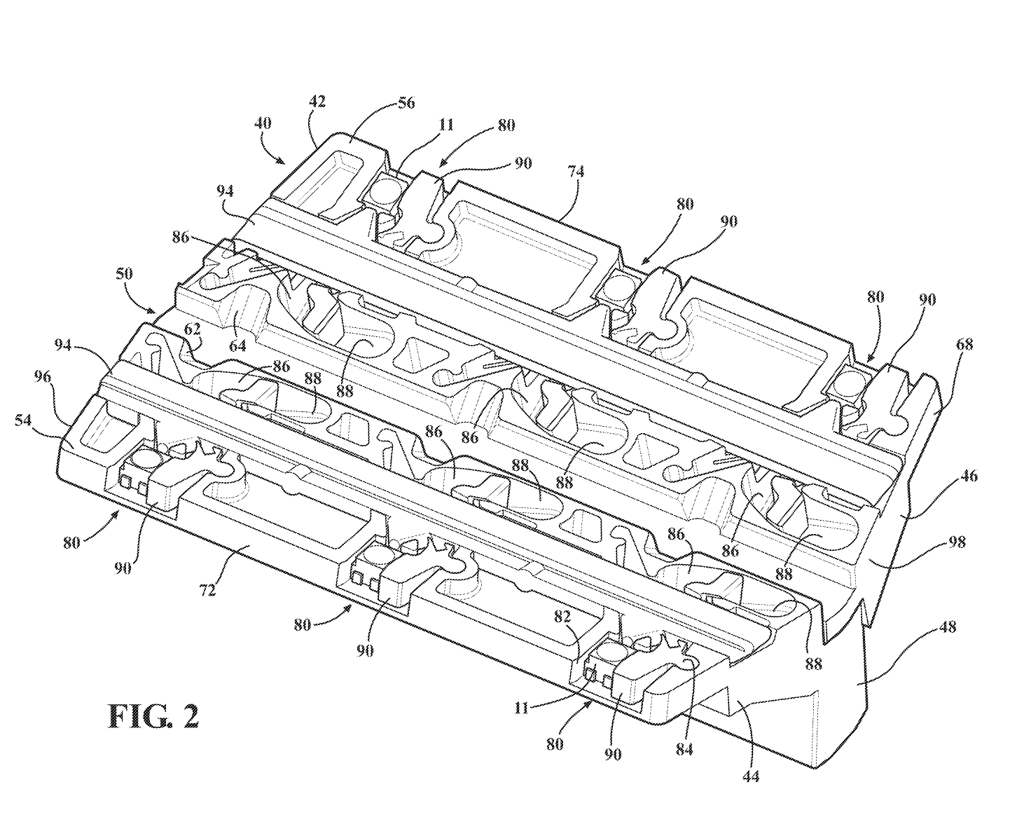

FIG. 1 shows an automated test system 10 for testing and sorting of miniature electronic devices 11 having electrical leads (FIG. 2) such as light emitting diodes (LEDs). Test system 10 includes a conveyor 12 and one or more loading stations, such as a first device loader 14 and a second optional device loader 16 that load electronic devices 11 onto carriers 40 at a transfer station 18. Electronic devices 11 are retained by clamping structures 90. Clamping structures 90 are moveable between an engaged position, in which electronic devices 11 are securable to carriers 40, and a disengaged position, in which electronic devices 11 are releasable from carriers 40. Test system 10 further includes one or more test stations, such as a first test station 20 and a second test station 22. An unloading station 25 is provided to unload electronic devices 11. A controller 28 is in electrical communication, either wired or wireless, with conveyor 12, device loaders 14, 16, test stations 20, 22 and unloading station 25 to sense and control the operations of each.

Controller 28 has a conventional structure and may include a processor, memory, storage media, communications devices, and input and output devices. For example, controller 28 can be a standard microcontroller that includes a central processing unit (CPU), random access memory (RAM), read only memory (ROM) and input/output ports receiving input signals and sending output signals needed to control the system and to perform certain process steps as described herein. The functions described herein are generally programming instructions stored in memory and are performed by the logic of the CPU. Of course, the controller that performs the functions described herein could be a microprocessor using external memory or could comprise a combination of such a microprocessor or microcontroller combined with other integrated logic circuits. Controller 28 is generally incorporated into or works with a personal computer with a screen and input devices, such as keyboards, for inputting commands for process control and for monitoring the process control.

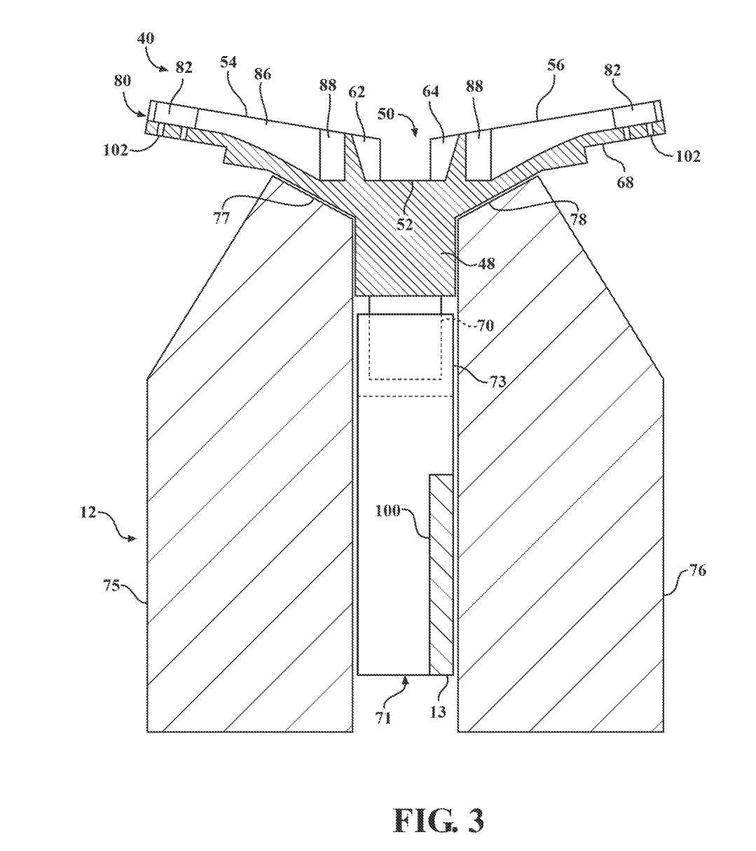

As shown in FIGS. 2 and 3, carrier 40 has a body 42 that may be fabricated as a one piece structure or as a multiple piece structure. Body 42 could be fabricated from plastic or other suitable materials.

Body 42 includes a first lateral portion 44 and a second lateral portion 46 that extend outward from a central portion 48. Lateral portions 44, 46 are spaced apart by a central channel 50. One or more locating features, such as pairs of first and second detents 62, 64 could be formed on body 42 to allow alignment of carrier 40 with respect to selected locations along conveyor 12, such as test stations 20, 22.

Central portion 48 extends downward with respect to a bottom surface 66 of first lateral portion 44 and a bottom surface 68 of second lateral portion 46. Central portion 48 could be located directly below central channel 50 and could be similar in lateral width.

Carrier 40 is configured to move in response to movement of conveyor 12. An engagement member 70 is formed on body 42 for operable engagement with conveyor 12. Engagement member 70 could be formed with any suitable geometry that allows engagement with conveyor 12. Engagement member 70 could be a downwardly extending tang, flange, projection, rod, post, hook, or any other suitable structure.

First and second lateral portions 44, 46 of body 42 respectively extend outward from central channel 50 to first and second lateral edges 72, 74 of body 42.

Carrier 40 includes a plurality of device retainers 80. In the illustrated embodiment, six device retainers 80 are provided with three located along each lateral edge 72, 74. Device retainers 80 could be, however, provided in any desired number.

Device retainers 80 are each defined in part by body 42, including a clamping area 82, a pivot 84, a pneumatic channel 86 and a pneumatic chamber 88. Each device retainer 80 also includes a clamping structure 90 and a biasing structure 92 (FIG. 4). Clamping structures 90 could be secured with respect to carrier 40 by retaining bars 94 that extend between first and second longitudinal ends 96, 98 of carrier 40, with each preventing separation of one or more clamping structures 90 from carrier 40. Retainer bars 94 may define a snap fit with carrier 40. Also, other structures could be utilized to retain clamping structures 90, such as features formed integrally with carrier 40 for mechanical fasteners, such as pins, screws, or bolts, as long as clamping structures 90 remain free to move between engaged and disengaged positions.

As shown in FIG. 3, conveyor 12 is configured to support and move carriers 40 in a continuous circuit and may be formed in any suitable geometry. Conveyor 12 could include a first rail 75 and a second rail 76 that are spaced apart. Rails 75, 76 include respective top surfaces 77, 78 that are configured to engage and support carrier 40. Top surfaces 77, 78 could be substantially continuous or could be non-continuous. Rails 75, 76 can be provided with additional structures that engage and support carriers 40, such as rollers (not shown).

A belt 13 is provided as the primary moving component of conveyor 12, such that objects that are moved by conveyor 12 are moved in correspondence to movement of belt 13. Other suitable structures could be provided in place of belt 13, such as a chain or cable.

Conveyor 12 is an indexing conveyor that indexes the position of belt 13 under the influence of a motor (not shown) or other suitable means. Belt 13 is moved by a predetermined amount in a step-wise fashion, typically with a delay between successive movements.

Rails 75, 76 extend around a circuit to define conveyor 12. Belt 13 is disposed between rails 75, 76 and also extends around the circuit. A longitudinal direction of belt 13 is defined as the direction in which belt 13 extends around the circuit defined by conveyor 12.

Belt 13 is oriented such that a primary surface 100 of belt 13 is substantially upright. For example, belt 13 could be oriented such that a line constructed orthogonal to primary surface 100 of belt 13 is generally horizontal.

A plurality of cleats 71 that are fixedly positioned at spaced locations with respect to one another along belt 13. Each cleat 71 defines a coupling recess 73 in which engagement member 70 of carrier 40 is received. With engagement member 70 disposed within coupling recess 73, indexing movement of belt 13 causes engagement of cleat 71 with engagement member 70, thereby moving carrier 40 in response to movement of belt 13.

As shown in FIGS. 4 and 5, device retainer 80 is defined primarily by the geometrical configuration of carrier 40. A clamping area 82 is defined by a substantially planar base surface 100. Base surface 100 is recessed with respect to top surface 54 and defines a lateral opening 104 at lateral edge 72 between first and second longitudinally-spaced, generally upstanding walls 106, 108. A stop shoulder 110 and a stop post 112 provide upstanding surfaces that are generally vertical and face toward lateral opening 104 to engage electronic device 11 and set a maximum degree of insertion for electronic device 11 in clamping area 82. An opening 113 is defined between stop shoulder 110 and stop post 112 for fluid communication with a pneumatic channel 86 so that pressurized air may flow from pneumatic channel 86 into clamping area 82 for electronic device 11 blow off, as will be described further herein.

One or more probe apertures 102 could extend through carrier 40 from base surface 100 to bottom surface 66 to provide access to the electrical leads of electronic devices 11. The electrical leads could, however, be accessed without providing probe apertures 102, depending upon the configuration of electronic device 11.

Adjacent to clamping area 82 and along second wall 108, pivot 84 is defined for pivotally connecting clamping structure to body 42. Pivot 84 may include an arcuate wall 116 defining and partially surrounding a pivot recess 118 in which a knuckle portion 120 is received. Knuckle portion 120 is a rounded member that depends outward from a body portion 122 of clamping structure 90 and is configured to allow pivoting of clamping structure 90 with respect to body 42 when received in pivot recess 118. Pivot 84 could be provided in other forms, such as a pin that extends through body portion 122 of clamping structure 90 and is connected to body 42, thereby allowing pivotal motion of clamping structure 90 with respect to carrier 40.

Proceeding inward from opening 113, pneumatic channel 86 is defined between boundary walls 124, 126 and tapers away from top surface 54 to deepen pneumatic channel 86 progressively. Pneumatic channel 86 continues to a curved wall 128 that is configured to provide clearance for pivotal motion of clamping structure 90 as it moves from the engaged position to the disengaged position.

Curved wall 128 proceeds to a spacer wall 130 that defines a vertical spacing between a bottom surface 132 of pneumatic channel 86 and an actuating portion 134 of clamping structure 90. Spacer wall 130 extends generally upright from bottom surface 132 to a generally planar surface 136. In the engaged position, actuating portion 134 of clamping structure 90 is closely adjacent to or in contact with planar surface 136 as it engages an upright shoulder 138 that extends upright from planar surface 136. Planar surface 136 and upright surface 138 define a boundary between pneumatic channel 86 and pneumatic chamber 88. With clamping structure 90 in the engaged position, engagement or adjacency of actuating portion 134 with one or both of planar surface 136 and upright surface 138 creates a substantial pneumatic seal between pneumatic channel 86 and pneumatic chamber 88 with respect to a flow path that could be defined between body 42 and actuating portion 134.

Upright shoulder 138 can engage actuating portion 134 to define a maximum limit of travel for clamping structure 90 in its engaged position. Opposite actuating portion 134, pneumatic chamber 88 is defined by body 42 and is more specifically defined by surrounding wall 141 of body 42. Each device retainer 80 further includes a wall 140, which may be adjacent to pneumatic channel 86 and is engageable with biasing structure 92. Biasing structure 92 is connected to clamping structure 90 and operates to bias it toward the engaged position, such as by impingement upon wall 140. For example, biasing structure 92 may be a wire spring fabricated from material such as music wire. Other structures could be used, such as a living hinge formed integrally with clamping structure 90.

A head portion 142 of clamping structure 90 is disposed within clamping area 82 and includes an engagement surface 144 for engaging electronic device 11. Engaging surface 144 may be substantially arcuate to allow a discrete point of contact to be established between engaging surface 144 and electronic device 11. Engaging surface 144 may also be inclined such that an acute angle is formed by engaging surface 144 with respect to a surface 100 as measured from the area of electronic device 11 between head portion 142 and wall 106. In order to allow transfer of electronic devices 11 into clamping area 82, a contoured end surface 146 is provided on head portion 142 and functions to guide electronic devices 11 into clamping area 82.

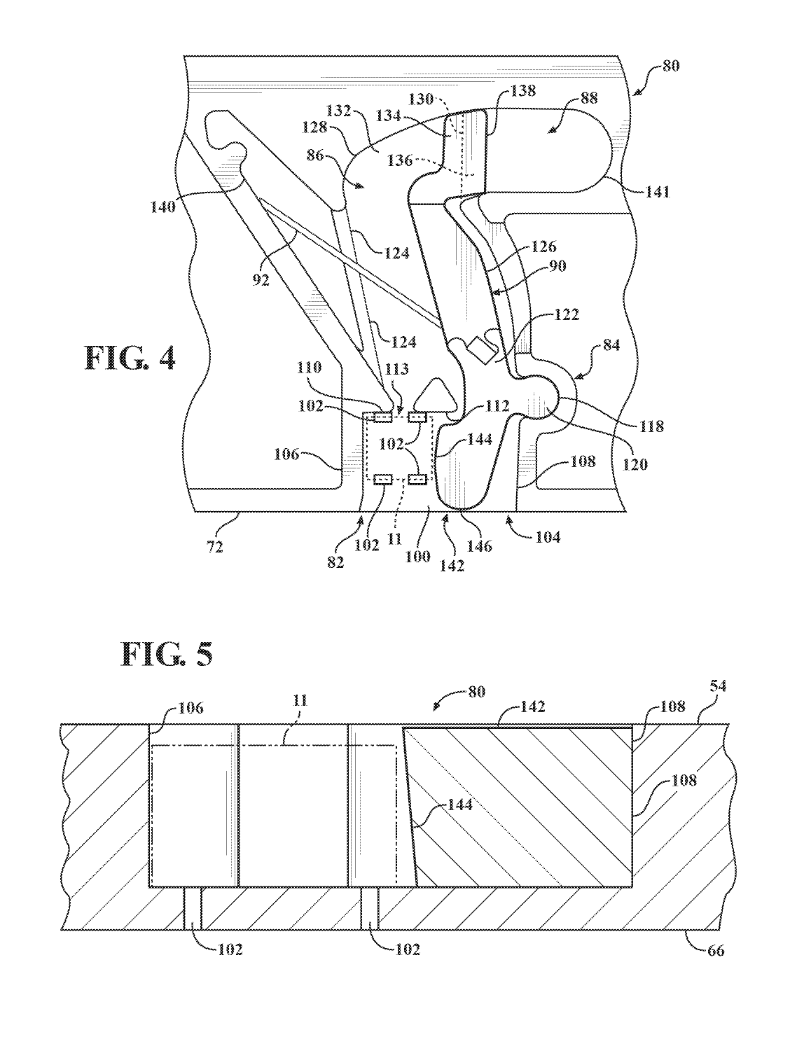

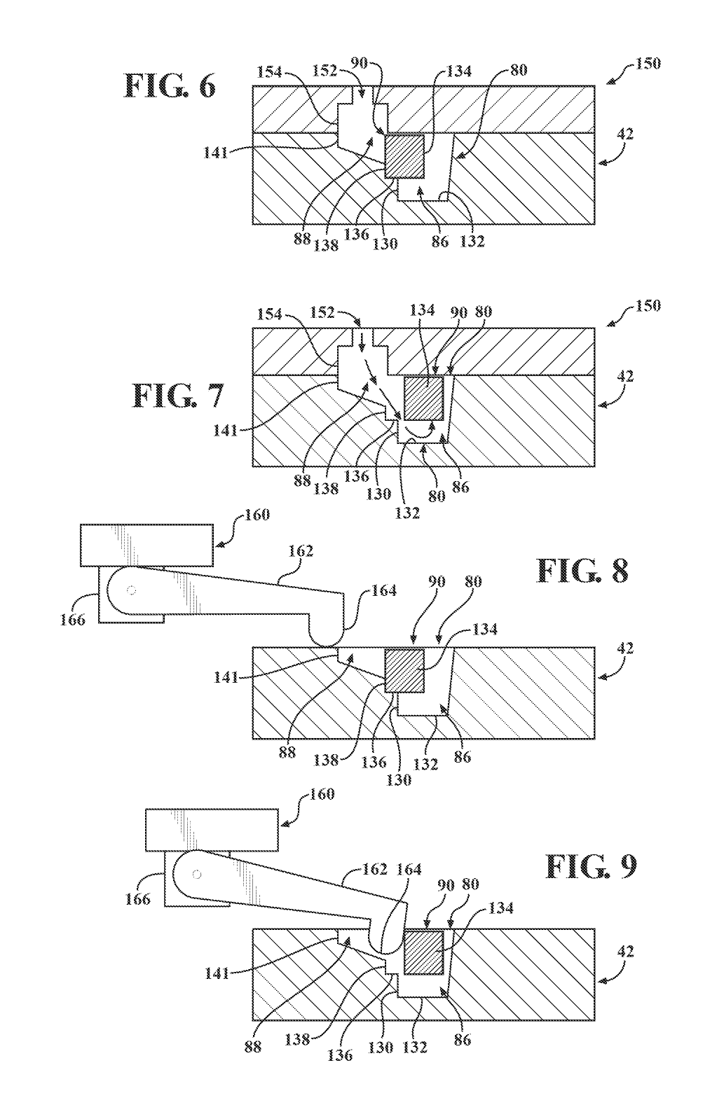

At unloading station 25, a manifold 150 in communication with a compressed air supply 152 is supported above conveyor 12 and comes into close proximity of top surfaces 54, 56 as carrier 40 passes under manifold 150, as shown in FIGS. 6 and 7. A port 154 in manifold 150 comes into registration with pneumatic chamber 88 of each device retainer 80. Ports 154 are provided in manifold 150 at selective locations along transfer station 25 to allow removal of electronic devices 11 from device retainers 80 at desired locations along unloading station 25.

Prior to application of compressed air at port 154, actuating portion 134 of clamping structure 90 is in engagement with or closely adjacent to one or both of planar surface 136 and an upright shoulder 138 (FIG. 6). Compressed air is supplied at port 154 into pneumatic chamber 88 (FIG. 7). The biasing force applied by biasing structure 92 is selected to be sufficient to resist movement of actuating portion 134 toward the disengaged position until sufficient pneumatic pressure has been achieved in pneumatic chamber 88 to effectively blow off electronic device 11. Once this pressure is reached, actuating portion 134 is moved away from upright shoulder 138 to establish a flow path between actuating portion 134 and upright shoulder 138, as well as planar surface 136. Pressurized air then flows into pneumatic channel 86 and is directed by pneumatic channel 86 toward opening 113, such that pressurized air is applied to move electronic device 11 through lateral opening 104, thereby ejecting electronic device 11 from device retainer 80. Thus, after application of pressurized air in pneumatic chamber 88, sufficient pressure is achieved, and clamping structure 90 is moved to its disengaged position such that it no longer engages electronic device 11 while actuating portion 134 traverses the width of planar surface 136. After this is done, the pressurized air is applied to electronic device 11.

Actuation of clamping structure 90 to load electronic devices 11 at transfer station 18 is achieved by mechanical means, as shown in FIGS. 8 and 9. An actuating assembly 160 provided at transfer station 18 includes a pivot arm 162 having a head 164 that depends downward therefrom. An actuator 166 controlled by controller 28 is operable to pivot arm 162.

Actuating assembly 160 may include two arms 162 for engagement with clamping structures 90 on both sides of central channel 50. Arms 162 ride upon top surfaces 54, 56, biased downward by self weight or affirmative biasing means (FIG. 8). Upon reaching one of the pneumatic chambers 88, head 164 enters pneumatic chamber 88 and comes into engagement with actuating portion 134. Engagement of head 164 with actuating portion 134 moves clamping structure 92 to the disengaged position. Electronic device 11 is then inserted into clamping area 82 in engagement with wall 106, stop shoulder 110, stop post 112 and base surface 100 by a mechanical or pneumatic transfer from device loaders 14, 16. Prior to the next indexing movement of conveyor 12, actuator 166 moves arm 162 along with head 164 upward out of engagement with actuating portion 134, which causes clamping structure 90 to move to its engaged position in response to the force exerted by biasing structure 92, thereby bringing engaging surface 144 into contact with electronic device 11 and securing it with respect to wall 106, stop shoulder 110, stop post 112, and base surface 100.

In operation, electronic devices 11 are loaded into device loaders 14, 16, where they are singulated. Following singulation, electronic devices 11 are transferred from device loaders 14, 16 to conveyor 12 at transfer station 18. Transfer station 18 moves electronic devices 11 individually from device loaders 14, 16 to carriers 40 using mechanical or pneumatic means.

Conveyor 12 indexes, or moves a predetermined amount, which sequentially moves electronic devices 11 into proximity with test stations 20, 22 for testing. By way of example, if electronic devices 11 are LEDs, they may be measured for light output parameters such as luminous flux and spectral light output. This could be done, for example, using a spectrophotometer and an integrating sphere. Other tests including measuring current or voltage. An exemplary device that can perform these functions is the Model 616 Test and Measurement Source, manufactured by Electro Scientific Industries, Inc. of Portland, Oreg.

Following testing, electronic devices 11 are unloaded at unloading station 25. Unloading station 25 could be configured to sort electronic devices 11 based on the results of the tests using a bin assembly 24 and an ejection assembly 26. Bin assembly 24 includes a large number of bins, and ejection assembly 26 ejects each electronic device 11 individually into a selected bin using, for example, selective application of pressurized air from manifold 150.

A typical cycle time for test system 10 contemplates a throughput of 32,000 devices per hour, which allows for a cycle time of 225 ms per device for each step in the process. In a typical system, conveyor 12 could be configured to index from one position to the next in 100 ms, leaving 125 ms for each step.

While the invention has been described in connection with certain embodiments, it is to be understood that the invention is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. A conveyor-mountable carrier for testing an electronic device having electrical leads, comprising:
a body having a clamping area that is defined by a base surface and at least one lateral stop surface, and a pneumatic channel for directing pressurized air toward the clamping area; and
a clamp that is moveably connected to the body and has an engaging portion that is positioned opposite the lateral stop surface of the body, wherein the clamp is moveable between an engaged position, in which the electronic device is securable to the body, and a disengaged position, in which the electronic device is releasable from the body.

2. The conveyor-mountable carrier of claim 1, wherein the engaging portion and the stop surface are engageable with the electronic device for securing the electronic device with respect to the body when the clamp is in the engaged position.

3. The conveyor-mountable carrier of claim 1, further comprising:
a biasing structure for biasing the clamp toward the engaged position.

4. The conveyor-mountable carrier of claim 1, wherein the body has a longitudinal edge and the base surface and the lateral stop surface each extend inward from the longitudinal edge of the body.

5. The conveyor-mountable carrier of claim 1, wherein the clamp is pivotally connected to the body.

6. The conveyor-mountable carrier of claim 1, wherein the clamp is pivotally connected to the body at a pivot defined by a knuckle portion of the clamp that is received within a recess formed on the carrier.

7. The conveyor-mountable carrier of claim 1, wherein the engaging portion is formed at a first end of the clamp, an actuating portion is formed at a second end of the clamp, and the clamp is pivotally connected to the body at a location between the first end of the clamp and the second end of the clamp.

8. The conveyor-mountable carrier of claim 7, wherein the body at least partially defines a pneumatic chamber adjacent to the actuating portion of the clamp for moving the clamp in response to pressurization of the pneumatic chamber.

9. The conveyor-mountable carrier of claim 8, wherein the body defines a shoulder adjacent to the pneumatic chamber, and the pneumatic channel extends from the shoulder to the clamping area, wherein an actuating portion of the clamp engages the shoulder when the clamp is in the engaged position to allow pressurization of the pneumatic chamber and is spaced from the shoulder when the clamp is in the disengaged position to allow pressurized air to travel from the pneumatic chamber to the pneumatic channel.

10. The conveyor-mountable carrier of claim 1, wherein at least one testing aperture that is formed through the base surface of the body for providing access to the electrical leads of the electronic device from an underside of the body.

11. A conveyor-mountable carrier for testing an electronic device having electrical leads, comprising:
a body having a clamping area that is defined by a base surface and at least one lateral stop surface, and a pneumatic channel for directing pressurized air toward the clamping area;
a clamp that is moveably connected to the body and has an engaging portion that is positioned opposite the lateral stop surface of the body, wherein the clamp is moveable between an engaged position, in which the engaging portion and the lateral stop surface are engageable with the electronic device for securing the electronic device with respect to the body, and a disengaged position, in which the electronic device is releasable from the body; and
a biasing structure that is configured to bias the clamp toward the engaged position.

12. The conveyor-mountable carrier of claim 11, wherein the body has a longitudinal edge and the base surface and the lateral stop surface each extend inward from the longitudinal edge of the body.

13. The conveyor-mountable carrier of claim 12, wherein the clamp is pivotally connected to the body.

14. The conveyor-mountable carrier of claim 11, wherein the clamp is pivotally connected to the body at a pivot defined by a knuckle portion of the clamp that is received within a recess formed on the carrier.

15. The conveyor-mountable carrier of claim 14, wherein the engaging portion is formed at a first end of the clamp, an actuating portion is formed at a second end of the clamp, and the clamp is pivotally connected to the body at a location between the first end of the clamp and the second end of the clamp.

16. The conveyor-mountable carrier of claim 15, wherein the body at least partially defines a pneumatic chamber adjacent to the actuating portion of the clamp for moving the clamp in response to pressurization of the pneumatic chamber.

17. The conveyor-mountable carrier of claim 16, wherein the body defines a shoulder adjacent to the pneumatic chamber, and the pneumatic channel extends from the shoulder to the clamping area, wherein an actuating portion of the clamp engages the shoulder when the clamp is in the engaged position to allow pressurization of the pneumatic chamber and is spaced from the shoulder when the clamp is in the disengaged position to allow pressurized air to travel from the pneumatic chamber to the pneumatic channel.

18. The conveyor-mountable carrier of claim 11, wherein at least one testing aperture that is formed through the base surface of the body for providing access to the electrical leads of the electronic device from an underside of the body.

19. A system for testing electronic devices having electrical leads, comprising:
a conveyor that extends between a loading station, a testing station and an unloading station;
a carrier that is mounted to the conveyor for movement therewith, the carrier including a body having a clamping area that is defined by a base surface and at least one lateral stop surface and a pneumatic channel for directing pressurized air toward the clamping area, and the carrier including a clamp that is moveably connected to the body, the clamp having an engaging portion that is positioned opposite the stop surface of the body, wherein the clamp is moveable between an engaged position, in which the electronic device is securable to the body, and a disengaged position, in which the electronic device is releasable from the body, and the carrier has a biasing structure that is configured to bias the clamp toward the engaged position; and
an actuator positioned at each of the loading station and the unloading station for moving the clamp from the engaged position to the disengaged position.

20. The conveyor-mountable carrier of claim 19, wherein at least one testing aperture that is formed through the base surface of the body for providing access to the electrical leads of the electronic device from an underside of the body.
